(19) United States
(12) Patent Application Publication
(10) Pub. No.: US 2004/0079286 A1
(43) Pub. Date: Apr. 29, 2004

(54) Method and apparatus for the pulse-wise supply of a vaporized liquid reactant

(76) Inventor: Sven Lindfors, Espoo (FI)

Correspondence Address: KNOBBE MARTENS OLSON & BEAR LLP, 2040 MAIN STREET, FOURTEENTH FLOOR, IRVINE, CA, 92614, US

(21) Appl. No.: 10/615,332

(22) Filed: Jul. 8, 2003

Related U.S. Application Data
(60) Provisional application No. 60/395,880, filed on Jul. 12, 2002.

(51) Int. Cl. C23C 16/00

(52) U.S. Cl. 118/715

(57) ABSTRACT

Methods and structures provide vaporized reactant from a liquid source to a vapor deposition reactor, such as an atomic layer deposition (ALD) reactor. A storage container holds the bulk of liquid reactant (or solid reactant dissolved in a liquid solvent) outside of the reactor hot zone(s), and so are not subject to decomposition from prolonged exposure to high temperatures. The storage container is in fluid communication with a vaporization chamber within a hot zone of the reactor, such that a high vapor pressure can be maintained within the vaporization chamber. Refilling the storage container outside of the hot zone(s) is simplified, and the bulk of the liquid reactant is not subject to prolonged exposure to destabilizing temperatures. At the same time, the advantages of maintaining a vaporization chamber within a hot zone are maintained. Furthermore, between deposition runs, or periodically when not needed, remaining liquid reactant in the vaporization chamber can be drained back to the storage container or to a separate drain container, where cooler temperatures are maintained.

### PRIORITY INFORMATION

This application claims the priority benefit under 35 U.S.C. § 119(e) of Provisional Application No. 60/395,880 filed Jul. 12, 2002, which is hereby incorporated by reference herein.

### BACKGROUND OF THE INVENTION

1. Field of the Invention

The present invention relates to supplying a vaporized liquid reactant to a vapor deposition apparatus (e.g., chemical vapor deposition or CVD), and more particularly to supplying vaporized liquid reactant for metal organic chemical vapor deposition (MOCVD) and atomic layer deposition (ALD).

2. Description of the Related Art

In the atomic layer deposition (ALD) technique, two or more different reactants are sequentially and alternatingly supplied to a reaction chamber in a pulse-wise manner. The reactants are supplied to the reaction chamber in the vapor state or in the gaseous state. However, many of the reactants are low vapor pressure liquids, such as metal organic liquids. These liquid reactants need to be vaporized before supply to the reactor. Although the evaporation of liquid reactants is well known in the field of chemical vapor deposition (CVD), the field of ALD imposes special requirements to such a vaporization system. An ALD apparatus requires the pulse-wise supply of a reactant. Furthermore, the reactants used in ALD are typically mutually very reactive, even at room temperature. Therefore two or more reactants used in ALD should be kept well separated and supplied to the reactor strictly sequentially. Furthermore, some of the reactants have particularly low vapor pressure, which requires special measures for the evaporation and transport to the reaction chamber.

A system for feeding vaporized reactant pulses to an ALD reaction chamber is disclosed in U.S. patent application Publication U.S. 2001/0054377 of applicant. In this system, a source container with liquid reactant is positioned in a hot zone together with a reaction chamber. The reactant is vaporized in the source container and pulses of reactant vapor are directed from the source container towards the reaction chamber by a system and method called “inert gas valving”. According to this method, through switching of an inert gas flow, the reactant vapor flow is alternatingly: (i) directed to the reaction chamber by an inert gas flow from the source container towards the reaction chamber and then (ii) prevented from flowing from the source container to the reaction chamber by an inert gas flow in a reverse direction in a part of the conduit connecting the source container and the reaction chamber.

By this inert gas valving system, a strict separation of two mutually reactive reactants, as required in ALD, can be achieved in a reliable way. One advantage of this method is that the switching valves are only exposed to inert gas and not to aggressive reactants that could corrode the valves. Furthermore, the valves can be installed outside the reactor's hot zone without a risk of condensing low vapor pressure reactant. Because the source container is installed in a common hot zone with the reaction chamber, condensation of the vaporized reactant between the source container and the reaction chamber can be adequately avoided. However, installing the source container inside the hot zone of the reactor is a very elaborate job, requiring dismantling of the reactor. An even more severe problem is encountered when the reactant material is thermally not very stable. This means that during prolonged exposure to the elevated temperatures needed for evaporation, detrimental effects could occur such as thermal decomposition, degradation or polymerization of the reactant.

A method for the pulse-wise supply of a reactant to a CVD system wherein the reactant vessel can be kept at room temperature is disclosed in U.S. Pat. No. 5,451,260 of Versteeg et al. According to the method, liquid reactant is pulse-wise supplied to an ultrasonic atomizing nozzle, which injects the atomized liquid reactant directly into a CVD reactor chamber. The deposition method described is pulsed CVD, wherein during the waiting time between the reactant pulses, the molecules on the substrate surface are allowed to reorder. It is doubtful that this dosing method would work for the sequential and alternating dosage of two or more mutually reactive reactants where a severe separation of reactants is required, as typically employed in ALD.

Another method for the vaporization and pulse-wise supply of a liquid reactant to a deposition reactor wherein the reactant vessel can be kept at ambient temperature is disclosed in U.S. Pat. No. 6,380,081 by Lee. According to the method disclosed by Lee, the temperature and the pressure of the liquid reactant are both increased such that the reactant remains in the liquid state. Then the liquid reactant is exposed instantaneously to a low pressure while maintaining the temperature, such that the reactant vaporizes immediately. In the method according to Lee, an intermediate reservoir is used wherein the liquid reactant is maintained at an increased temperature, which is problematic for liquid reactant materials that have a limited thermal stability. Liquid reactant material that remains in the reservoir between two deposition runs can degrade during the long residence time in the reservoir. Furthermore, it is questionable whether sequential pulses of different, mutually reactive materials can be kept sufficiently separated using the method of Lee.

The two last methods require the dosage of liquid pulses of an extremely small size as needed for the monolayer coverage in ALD. This is very difficult. Furthermore, ALD often employs a combination of a liquid reactant and a gaseous reactant. According to the methods described above, the liquid reactant requires the generation of liquid pulses whereas the gaseous reactant requires the generation of gas pulses. It is difficult to synchronize the liquid and gas pulses so that they are timed accurately and sequentially in a reproducible way. Furthermore, it is very questionable whether the short pulse times used in ALD, on the order of 100 milliseconds or less, are possible using liquid reactant delivery.

It is an object of the present invention to provide a method for the delivery of a vaporized solid or liquid reactant having a very low vapor pressure to a vapor deposition reaction chamber which avoids the disadvantages described above and which utilizes conventional evaporation, wherein a quantity of liquid or solid reactant is in coexistence with its vapor.

### SUMMARY OF THE INVENTION

According to one aspect of the invention, a method is provided whereby a liquid reactant is stored in a storage container at a first low temperature T1 which is low enough so that it does not destabilize the reactant. For the purpose of use, an amount of liquid reactant is fed from the storage container to a vaporization chamber such that the vaporization chamber is partially filled with the liquid reactant. The vaporization chamber is positioned in a hot zone at a second temperature T2, which is higher than T1 and high enough to produce a sufficient amount of vaporized reactant. The vaporized reactant is collected above the surface of the reactant in the upper part of the vaporization chamber. The vaporized reactant is fed from the vaporization chamber to the reaction chamber that is positioned in a hot zone at a third temperature T3 that is higher than T1.

According to another aspect of the invention, a liquid reactant is stored in a storage container at a first low temperature T1 which is low enough so that it does not destabilize the reactant. For the purpose of use, an amount of liquid reactant is fed from the storage container to a vaporization chamber such that the vaporization chamber is partially filled with the liquid reactant. The vaporization chamber is positioned in a hot zone at a second temperature T2, which is higher than T1 and high enough to produce a sufficient amount of vaporized reactant. The vaporized reactant is collected above the liquid surface in the upper part of the vaporization chamber. The vaporized reactant is fed from the vaporization chamber to the reaction chamber in a pulse-wise manner through switching an inert gas flow according to the method of inert gas valving. The reaction chamber is positioned in a hot zone at a third temperature T3 that is higher than T1.

According to another aspect of the invention, a method for providing vapor phase reactant from solid or liquid source includes supplying a liquid comprising a precursor from a storage container to a vaporization chamber, which is kept at a higher temperature than the storage container. Precursor is vaporized in the vaporization chamber and transported to a reaction chamber, in which a vapor deposition process is conducted. Unvaporized liquid is drained from the vaporization chamber, without opening the vaporization chamber, after conducting the vapor deposition process.

According to another aspect of the invention, the vaporization chamber is provided with a drain and after use, the remaining non-vaporized reactant in the vaporization chamber is removed from the vaporization chamber by draining.

In the preferred embodiment of the invention, the vaporization chamber and the reaction chamber are installed in a common hot zone so that condensation between the vaporization chamber and the reaction chamber is prevented and cumbersome heating of reactant conduits with heating jackets is not needed.

### BRIEF DESCRIPTION OF THE DRAWINGS

FIG. 1 schematically illustrates an ALD reactor in accordance with a first embodiment of the invention

FIG. 2 schematically illustrates an ALD reactor in accordance with a second embodiment of the invention.

### DETAILED DESCRIPTION OF THE PREFERRED EMBODIMENTS

The utilization of a liquid or solid reactant with very low vapor pressure at room temperature generally entails heating the liquid or solid reactant to temperatures substantially above room temperature, such that the reactant at the increased temperature has sufficient vapor pressure to provide an adequate supply of vaporized reactant to a reaction chamber. For ALD processes, an “adequate” supply will saturate the substrate surface(s) in a self-limited reaction. In such a supply system, all components and conduits should be carefully heated and isolated to avoid any cold spots, as such cold spots would result in condensation of the vaporized reactant. More specifically, in the path from a vaporization chamber, in which liquid or solid reactant is vaporized, to the reaction chamber where the reactant is utilized for the deposition of a film onto a substrate, the temperature of the conduits, valves and other components should be constant or continuously increasing to guarantee that no condensation occurs. When the required vaporization temperature is high, say 200° C. or higher, this is not simple to achieve. Furthermore, as a reactant is consumed, an empty reactant container needs to be replaced and exchanged for a filled one. Dismantling thermal isolation and heating jackets and reinstalling them again is a labor intensive, time-consuming process during which the reactor productivity is lost. It has therefore been considered very beneficial to place the vaporization chamber and the reaction chamber in a common hot zone.

However, the placement of a vaporization chamber containing an amount of liquid or solid reactant and a reaction chamber inside a common hot zone has some disadvantages too. First of all, in order to place the container inside the hot zone, the hot zone needs to be opened to allow access and closed again after placing the vaporization chamber. This is a time-consuming procedure. Every time the reactant is consumed and the vaporization chamber is empty, it needs to be replaced by a filled vaporization chamber. Another disadvantage is that many low vapor pressure reactants might not have a long-term stability at the high temperature required for vaporization and transport in the vapor phase to the reaction chamber.

Therefore, the preferred embodiments provide an apparatus for the deposition of thin films, utilizing low vapor pressure reactants. The apparatus includes a vaporization chamber positioned inside a hot zone, jointly with a reaction chamber, with feed means to feed the reactant to the vaporization chamber. In a preferred embodiment, the vaporization chamber is further provided with a drain to drain unvaporized reactant from the vaporization chamber.

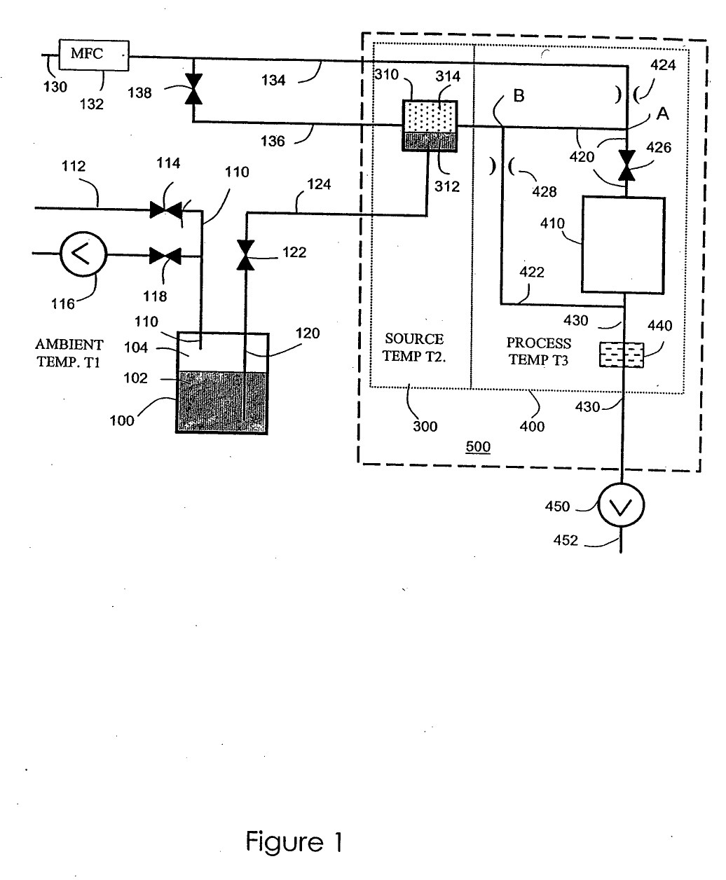

The present invention will further be explained by reference to particular embodiments illustrated in the figures. In FIG. 1 a system according to one embodiment of the invention is schematically shown. A storage container 100, at a temperature T1, which is typically ambient temperature, contains an amount of liquid reactant 102. The upper space 104 in the container 100 is filled with inert gas. The inert gas may contain a low amount of reactant vapor, corresponding to the vapor pressure of the reactant at the storage temperature. Via feed line 110, the storage container 100 can be filled with pressurized inert gas by opening valve 114 to an inert gas feed line 112. Alternatively, storage container 100 can be evacuated by opening valve 118 to a pump 116. The storage container 100 is connected with a vaporization chamber 310 through a rise tube 120 and a liquid reactant feed line 124, closable by valve 122. The liquid reactant feed line 124 discharges into the lower part of the vaporization chamber 310.

The vaporization chamber 310 is positioned in a hot zone 300 at a source temperature T2. Temperature T2 is higher than T1 and so high that the vapor pressure of the reactant, corresponding with T2, is sufficiently high to facilitate the production and transport to the reaction chamber of an adequate amount of vaporized reactant. Typically, T2 is close to or equal to the process temperature T3. In the upper part of the vaporization chamber, reactant vapor 314 is collected above the hot, unvaporized reactant 312. The vaporized reactant 314 is fed to a reaction chamber 410, which is positioned in a hot zone 400 at T3, via a vaporized reactant conduit 420. T3 is higher than T1 and preferably T3 is higher than or equal to T2. Reacted vapors and reaction by-products are exhausted from the reaction chamber 410 via an exhaust conduit 430 connected to a pump 450 that is provided with a pump exhaust 452. The exhaust conduit 430 is provided with a fore line filter 440.

The vaporized reactant 314 can be fed to the reaction chamber 410 in a pulse-wise manner through a system of inert gas valving, as described in patent publication U.S. 2001/0054377, the disclosure of which is incorporated by reference herein. This system comprises a feed of inert gas 130, a flow control device, such as a mass flow controller 132, an inert gas supply line 136 provided with a pulsing valve 138 to supply inert gas pulse-wise to the vaporization chamber 310, and an inert gas purge line 134 provided with an orifice 424. Furthermore, the inert gas valving system comprises a bypass conduit 422, at one end in communication with the vaporized reactant conduit 420 and at the other end in communication with the exhaust conduit 430. The bypass conduit 422 is provided with an orifice 428. The inlet side of the reaction chamber 410 is provided with a gate valve 426.

As shown in FIG. 1, the hot zone 300 at T2 accommodating the vaporization chamber 310 and the hot zone 400 at T3 accommodating the reaction chamber 410 are adjacent to each other and intimately connected. Preferably, the two hot zones form a common hot zone with at least some of the surrounding isolation material in common, such that the two hot zones 300, 400 are both thermally insulated from the storage container 100. The hot zones can be provided with separate heaters and temperature controllers. These separate heater and temperature controllers can be in free thermal communication with one another to facilitate the establishment of a uniform temperature (T2=T3) throughout the entire hot zone 300, 400. Alternatively, the separate heaters and controllers can be used to impose different temperatures T2 and T3. In the latter arrangement, although the hot zones 300 and 400 are intimately connected, thermal isolation such as isolating material or a gap is preferably present at their interface so that a temperature difference of, e.g., 50° C. between the two zones can easily be imposed. The intimate connection of zones 300 and 400 entails that they share a relatively large area interface that is well isolated from room ambient and from the storage container 100. Furthermore, both hot zones 300 and 400 can be accommodated within a single low-pressure zone 500, as shown.

In describing the operation of the illustrated system, it will first be assumed that the vaporization chamber 310 is initially empty. The storage container 100 can be pressurized by opening valve 114 so that the storage container 100 is in communication with the inert gas feed line 112. After pressurizing the storage container 100, valve 114 can be closed again.

To feed liquid from the storage container 100 to the vaporization chamber 310, valve 122 in the liquid reactant feed line 124 is opened so that the vaporization chamber 310 is partially filled with liquid reactant 312. The amount of liquid charged into the vaporization chamber 310 can be controlled in various ways. For example the valve 122 can be opened for a predetermined amount of time. In combination with a controlled amount of overpressure in the storage container 100 and a fixed flow resistance of line 124, this will result in a reproducible charging of the vaporization chamber 310. Alternatively, a liquid mass flow measuring device (liquid MFM) or control device (not shown) can be included in line 124 so that the amount of liquid charged into the vaporization chamber 310 is measured or actively controlled. Alternatively, the vaporization chamber 310 can be provided with some type of surface level sensing device. The vaporization chamber 310 can be regularly refilled, preferably between deposition runs, or can be refilled only when the surface level of unvaporized liquid 312 in the vaporization chamber 310 falls below a predetermined level.

After charging the vaporization chamber 310, valve 122 is closed again. Then the liquid reactant 312 in the vaporization chamber 310 is heated until it assumes the temperature of the vaporization chamber 310. Typically this occurs by controlling temperature of the vaporization chamber 310 at a constant value and compensating for the heat that is absorbed by the cold liquid reactant. When the reactant has assumed the vaporization temperature, reproducible feed of vaporized reactant 314 to the reaction chamber 410 can start. Depending on circumstances and requirements, either a continuous supply of vaporized reactant, whether or not in combination with inert gas, or a pulse-wise supply of vaporized reactant to the reaction chamber, can be applied.

After use, the remaining non-vaporized reactant 312 in vaporization chamber can be removed in the following way. By closing the gate valve 426, and controlling a flow of inert gas by the mass flow controller 132, the pressure inside the vaporization chamber 310 is increased. Then, the upper space 104 of the storage container 100 is evacuated by opening valve 118 to the pump 116 until the pressure in storage container 100 is lower than the pressure in the vaporization chamber 310. Then valve 122 is opened so that liquid reactant 312 flows from the vaporization chamber 310 to the storage container 100 until all the unvaporized reactant 312 is drained from the vaporization chamber 310. A liquid flow-measuring device, installed in line 124 and not shown in FIG. 1, can be used to verify if the draining has been complete. After completion of the draining procedure, valves 118 and 122 are closed and the gate valve 426 is opened again. The draining of the liquid reactant can be followed by a purge procedure with inert gas to vaporize the remaining traces of reactant from the vaporization chamber 310.

The draining of the vaporization chamber can be performed at any suitable interval. It is possible, for example, to charge the vaporization chamber with reactant for one run and drain the remaining reactant after the run. Similarly, it can be decided to drain the vaporization chamber whenever not in use. However, the interval can also be a number of runs, with the vaporization chamber being drained for the dead period between a pair of deposition runs. Alternatively, a time interval can be chosen such as every day or every three days or every week. Also a combination of the two can be chosen, such as draining every five runs but at least every two days. The most suitable interval depends on the circumstances, such as the utilization of the system and the thermal stability of the reactant.

The pulse-wise supply of vaporized reactant to the reaction chamber by the system and the method of inert gas valving will now be explained. A continuous flow of inert gas is established by means of the flow control device 132. During the time that no reactant is supplied to the reaction chamber 410, valve 138 is closed and the flow of inert gas is directed via the purge conduit 134, the orifice 424 and the conduit 420 to the reaction chamber 410. The bypass conduit 422, including the orifice 428, is dimensioned such that part of the inert gas flows through the reaction chamber 410 to the pump 450, whereas another part of the inert gas flows through the conduit 420, from point A to point B and via the bypass conduit 422 in the direction of the pump 450. By the inert gas flow in section AB, a diffusion barrier of inert gas flow is generated, preventing the vapor flow or diffusion of vaporized reactant to the reaction chamber 410.

For the supply of vaporized reactant to the reaction chamber 410, valve 138 is opened. The orifice 424 is dimensioned as a restriction such that the majority of the inert gas flows to the vaporization chamber 310 and carries vapor from the vaporization chamber 310 to the reaction chamber 410. The small amount of inert gas that still flows through the purge line 134 is effective in preventing the diffusion of reactant into the purge line 134 from point A. A small fraction of the flow from the vaporization chamber 310 to the reaction chamber 410 is diverted through the bypass conduit 422. It should be noted that the presence of the bypass circuit results in some unavoidable loss of reactant during the supply of vaporized reactant to the reaction chamber 410, which is a negative side effect.

The reason to install the bypass conduit is to be able to establish a diffusion barrier with inert gas during periods in which reactant should not be supplied to the reaction chamber. An advantage of this inert gas valving system and method is that reactant vapor pulses can be created by switching an inert gas flow, wherein the inert gas flow pulsing valve 138 can be installed outside the hot zones 300, 400. Furthermore, valve 138 is only exposed to inert gas and not to the reactant vapor, which can be corrosive.

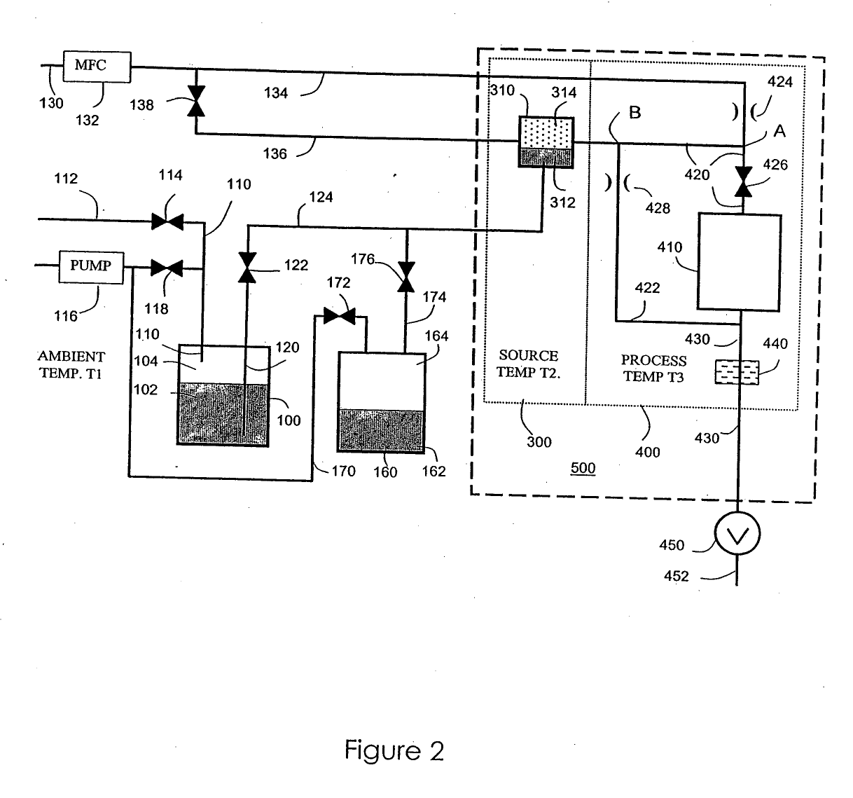

A second embodiment of the invention is shown in FIG. 2, wherein similar parts are indicated by similar reference numerals as in FIG. 1. The system shown in FIG. 2 comprises, in addition to the features presented in FIG. 1, a separate drain container 160 to collect drained reactant 162. The drain container 160 is connected to the pump 116 via a pump line 170, which is closable by valve 172. The drain container 160 is connected to the liquid reactant supply line 124 via a drain conduit 174 that is provided with a valve 176. An advantage of the illustrated configuration is that, not only can the vaporization chamber 310 be drained, but the hot part of the liquid reactant feed conduit 124 can also be drained. However, alternatively, the drain line 174 might be separately connected to the vaporization chamber 310.

Another advantage with the configuration shown in FIG. 2 is that the risk of contaminating the reactant in the storage container 100 with the reactant drained from the vaporization chamber 310 is avoided. The procedure to charge the vaporization chamber 310 with liquid reactant is the same as described in relation to FIG. 1. The draining procedure is similar but is applied to the different hardware configuration so that the drained reactant is collected in the drain container 160. By closing gate valve 426, and controlling a flow of inert gas by the mass flow controller 132, the pressure inside the vaporization chamber 310 is increased. Then, the upper space 164 of the drain container 160 is evacuated by opening valve 172 in the evacuation conduit 170 to the pump 116 until the pressure in the drain container 160 is lower than the pressure in the vaporization chamber 310. Then valve 176 is opened so that liquid reactant 312 flows from the vaporization chamber 310 to the drain container 160 via the liquid reactant conduit 124 and the drain conduit 174 until all the unvaporized reactant 312 is drained from the vaporization chamber 310. In the illustrated configuration of FIG. 2, valves 118 and 122 are closed so that the reactant is drained to the dedicated drain container 160. A liquid flow-measuring device, installed in the drain conduit 174 and not shown in FIG. 2, can be used to verify whether the draining has been complete. After completion of the draining procedure, valves 172 and 176 are closed and gate valve 426 is opened again. The draining of the liquid reactant can be followed by a purge procedure with inert gas to vaporize the remaining traces of reactant from the vaporization chamber 310.

The system according to FIGS. 1 and 2 can also be supplied with a solvent system to clean the conduits that are exposed to liquid reactant. For example, when the storage container 100 needs to be replaced because it is empty, several conduits should be disconnected. When such a conduit still contains reactant, either in liquid form or adsorbed on the wall, a reaction with ambient air and hence contamination of the conduits can occur. This can be prevented by flushing the conduits with a suitable solvent that removes all remainder of the reactant.

In another embodiment of the invention, a solid source for vapor reactant, dissolved in a solvent, can be fed from a storage container to a vaporization chamber in a manner as described above. Vaporized reactant, together with vaporized solvent can be fed to the reaction chamber. The solvent should be selected such that it does not react with the reactant and it is inactive in the deposition process. Alternatively, when the solvent is a high vapor pressure solvent, it can be evaporated from the vaporization chamber until only the solid reactant material is left before using the reactant material. As the solid precursor typically exhibits a very low vapor pressure, the evaporation of a high vapor pressure solvent should only result in a very small loss of reactant material. Even in this case, after use the unvaporized solid reactant can be removed from the vaporization chamber by flushing it with the solvent and draining the solvent with the reactant dissolved in it from the vaporization chamber.

### EXAMPLE 1

An example is now presented of a reactant and a process for which the systems and methods described above can be used beneficially. Consider the deposition of tantalum oxide from tantalum pentaethoxide (TAETO) as a metal source material. The vapor pressure of TAETO is low. At a temperature of 160° C., the vapor pressure is about 1 Torr. Therefore, heating to temperatures in the 150° C. to 200° C. range or higher are preferably employed to facilitate sufficient evaporation and vapor transport for a deposition process. This can conveniently be achieved when the vaporization chamber, containing the liquid to be evaporated, is placed in the hot zone of the deposition reactor. TAETO readily reacts with water vapor. Water has a much higher vapor pressure than TAETO. Therefore the water container, from which the water is evaporated, should be placed outside the hot zone of the reaction chamber. Although TAETO and water vapor are mutually so reactive that it is difficult to control the reaction, this chemistry can conveniently be exploited in an ALD process by exposing a substrate alternatingly and sequentially to vapor pulses of water and TAETO. A reaction chamber temperature of 220° C. was used and a vaporization chamber temperature of 200° C. was selected. Remaining TAETO in the vaporization chamber was drained and collected in a drain container at least every day.

Although the foregoing invention has been described in terms of certain preferred embodiments, other embodiments will be apparent to those of ordinary skill in the art. For example, while illustrated in the context of an ALD reactor, certain features and advantages of the embodiments described herein will have application to other types of deposition reactors. Additionally, while particularly advantageous for placement of the storage container outside the hot zone(s) of a vapor deposition reactor with the vaporization container inside a hot zone, certain features and advantages of the separated storage container and vaporization chamber are applicable for other positions relative to the hot zone(s). Additionally, other combinations, omissions, substitutions and modification will be apparent to the skilled artisan, in view of the disclosure herein. Accordingly, the present invention is not intended to be limited by the recitation of the preferred embodiments, but is instead to be defined by reference to the appended claims.

We claim:

1. A system for feeding a low vapor pressure reactant to a reaction chamber, comprising:
a storage container at a first temperature T1, the storage container containing an amount of liquid reactant;
a vaporization chamber positioned in a hot zone at a second temperature T2, higher than T1, the vaporization chamber connected with the storage container through a liquid reactant feed line and configured to be partially filled with liquid reactant and to collect vaporized reactant above a surface of the liquid reactant in an upper part of the vaporization chamber; and
a reaction chamber positioned in a hot zone at a third temperature T3, wherein T3 is higher than T1, the reaction chamber being connected to the vaporization chamber through a vaporized reactant feed conduit.

2. The system of claim 1, further comprising a drain at one end connected to a bottom part of the vaporization chamber to drain residual reactant after use.

3. The system of claim 2, wherein the drain comprises the liquid reactant feed line in communication with a pump and the storage container.

4. The system of claim 2, wherein the drain comprises a drain conduit communicating at one end with the vaporization chamber and at the other end with a drain container to collect drained reactant.

5. The system of claim 4, further comprising a liquid mass flow measuring device in the drain conduit.

6. The system of claim 1, wherein T3 is higher than or equal to T2.

7. The system of claim 1, wherein the hot zone of the vaporization chamber and the hot zone of the reaction chamber are in intimate contact.

8. The system of claim 1, wherein the hot zone of the vaporization chamber and the hot zone of the reaction chamber are in free thermal communication with each other and thermally insulated from the storage container.

9. The system of claim 1, wherein the hot zone of the vaporization chamber is part of the hot zone of the reaction chamber.

10. The system of claim 1, wherein vaporized reactant is directed from the vaporization chamber to the reaction chamber through an inert gas valving system.

11. The system of claim 1, further comprising a liquid flow control device in the liquid reactant feed conduit.

12. A method for providing vapor phase reactant from solid or liquid source, comprising:
supplying a liquid comprising a precursor from a storage container to a vaporization chamber, the vaporization chamber being at a higher temperature than the storage container;
vaporizing the precursor in the vaporization chamber;
transporting the vaporized precursor to a reaction chamber;
conducting a vapor deposition process using the vaporized precursor in the reaction chamber; and
draining unvaporized liquid from the vaporization chamber after conducting the vapor deposition process without opening the vaporization chamber.

13. The method of claim 12, wherein the liquid is the precursor.

14. The method of claim 13, wherein vaporizing comprises maintaining an unvaporized liquid in the vaporization chamber and generating vaporized precursor above the unvaporized liquid.

15. The method of claim 12, wherein the liquid comprises a solid reactant source dissolved in a solvent.

16. The method of claim 15, wherein vaporizing the precursor comprises vaporizing the solvent and vaporizing the solid reactant source.

17. The method of claim 16, wherein draining comprises providing solvent to the vaporization chamber to dissolve remaining solid reactant source and draining a resultant solution.

18. The method of claim 12, wherein draining comprises returning the unvaporized liquid to the storage container.

19. The method of claim 18, wherein draining further comprises employing a pump.

20. The method of 12, wherein draining comprises removing the unvaporized liquid to a dedicated drain container.

21. The method of claim 12, wherein the storage container is kept at a temperature at which the precursor is stable.

22. The method of claim 21, wherein the vaporization chamber is kept at a vaporization temperature below the boiling point of the precursor.

23. The method of claim 22, wherein transporting comprises flowing the vaporized precursor along conduits maintained at or above the vaporization temperature.

24. The method of claim 22, wherein the vaporization chamber is maintained within a first hot zone in intimate contact with a second hot zone accommodating the reaction chamber.

25. The method of claim 24, wherein the first hot zone and the second hot zone share at least some insulating elements.

26. The method of claim 22, wherein the vaporization chamber and the reaction chamber are maintained within a single hot zone.

27. The method of claim 22, wherein transporting comprises supplying pulses of the vaporized precursor to the reaction chamber alternatingly with pulses of at least one other precursor.

28. The method of claim 27, wherein transporting comprises alternatingly stopping and allowing flow of the vaporized precursor from the vaporization chamber to the reaction chamber with an inert gas diffusion barrier.

29. The method of claim 28, wherein alternatingly stopping and allowing flow with an inert gas diffusion barrier comprises controlling valves for an inert gas flow outside of a hot zone accommodating the vaporization chamber.

30. The method of claim 12, wherein the vapor deposition comprises atomic layer deposition.

31. The method of claim 12, wherein draining is conducted at regular intervals between a predetermined number of depositions.

32. The method of claim 12, wherein draining is conducted regularly between deposition runs after a predetermined period of time.

33. The method of claim 12, further comprising periodically refilling the vaporization chamber with liquid from the storage container.

34. The method of claim 33, wherein periodically refilling comprises sensing a surface level of unvaporized liquid in the vaporization chamber has fallen below a predetermined level.
